(19) United States
(12) Patent Application Publication
(10) Pub. No.: US 2026/0072074 A1
(43) Pub. Date: Mar. 12, 2026

(54) PRESSING MODULE CAPABLE OF MULTI-POINT FORCE APPLICATION AND MULTI-POINT TEMPERATURE CONTROL AND SEMICONDUCTOR PACKAGING COMPONENT TESTING DEVICE HAVING THE SAME

(71) Applicant: King Yuan ELECTRONICS CO., LTD., Hsinchu City (TW)

(72) Inventors: Kuo-Jung Wu, Hsinchu City (TW); Hsing-Yueh Liang, Hsinchu City (TW); Po-Wei Liao, Hsinchu City (TW); Hung-Chi Wei, Hsinchu City (TW)

(73) Assignee: King Yuan ELECTRONICS CO., LTD., Hsinchu City (TW)

(21) Appl. No.: 19/025,592

(22) Filed: Jan. 16, 2025

(30) Foreign Application Priority Data
Sep. 9, 2024 (TW) 113134120

(51) Int. Cl. G01R 31/28

(52) U.S. Cl. CPC G01R 31/2863; G01R 31/2875; G01R 31/2877

(57) ABSTRACT

A pressing module capable of multi-point force application and multi-point temperature control and a semiconductor packaging component testing device having the same are provided. The pressing module is capable of simultaneously applying a plurality of forces, which may be the same or different, to a plurality of chips on a semiconductor packaging component, and simultaneously producing same or different temperature control effects on the chips. The device utilizes a plurality of force-generating units to drive a plurality of pressing blocks to respectively apply forces to the chips on the semiconductor packaging component, and utilizes respective temperature regulating units on the pressing blocks to respectively heat or cool the chips.

### CROSS-REFERENCE TO RELATED APPLICATION

This non-provisional application claims priority under 35 U.S.C. § 119(a) to Patent Application No. 113134120 filed in Taiwan, R.O.C. on Sep. 9, 2024, the entire contents of which are hereby incorporated by reference.

### BACKGROUND

### Technical Field

The present disclosure relates to a pressing module and a semiconductor packaging component testing device having the same, and in particular, to a semiconductor packaging component testing device featuring a pressing module capable of applying multiple forces and generating various temperature control effects.

### Related Art

In conventional semiconductor packaging component testing technology, a single pressing head and a single temperature controller are typically used. Through the contact and force applied by the pressing head to the chip, the temperature controller can heat or cool the chip. Additionally, the force ensures complete electrical contact between the semiconductor packaging component and the test socket.

However, with advancements in packaging technology, techniques have progressed to include 2.5D and 3D packaging technologies. Well-known advanced packaging methods include Integrated Fan-Out (InFO) and chip-on-wafer-on-substrate (CoWoS) packaging, both of which can be used to package multiple chips assembled side-by-side. In other words, the top surface of a semiconductor packaging component using advanced packaging technology includes multiple chips, which may vary in area, thickness, and even thermal design power (TDP) for each chip.

Accordingly, conventional testing equipment using a single pressing head and a single temperature controller is no longer suitable for testing semiconductor packaging components with advanced packaging. A single pressing head may not contact all chips on the packaging component uniformly and cannot control the temperature of each chip individually. This limitation is even more pronounced for chips with varying TDP, as it can lead to uneven temperature distribution across the entire package, potentially causing thermal crosstalk issues. Such issues may impact the reliability of the semiconductor package and the accuracy of the testing equipment.

### SUMMARY

In view of this, embodiments of the present disclosure provide a pressing module capable of multi-point force application and multi-point temperature control and a semiconductor packaging component testing device having the same. The pressing module can apply multiple downward forces of the same or varying magnitudes to multiple chips on the semiconductor packaging component simultaneously, while also enabling multiple, simultaneous temperature control effects at the same or different temperatures.

An embodiment of the present disclosure provides a pressing module capable of multi-point force application and multi-point temperature control. The module mainly includes a plurality of pressing blocks, a plurality of force-generating units, a plurality of temperature regulating units, and a controller. The pressing blocks respectively correspond to a plurality of chips on a semiconductor packaging component. The force-generating units are respectively coupled to the plurality of pressing blocks. The temperature regulating units are respectively arranged on the pressing blocks. The controller is electrically connected to the force-generating units and the temperature regulating units. The controller is adapted to control the force-generating units to drive the pressing blocks to respectively apply forces to the chips on the semiconductor packaging component, and the controller is adapted to control the temperature regulating units to respectively heat or cool the plurality of chips on the semiconductor packaging component.

Another embodiment of the present disclosure provides a pressing module capable of multi-point force application and multi-point temperature control. The module mainly includes a plurality of pressing blocks, a plurality of force-generating units, a plurality of temperature regulating units, an actuator, and a controller. The pressing blocks respectively correspond to the plurality of chips on the semiconductor packaging component. The force-generating units are coupled to the pressing blocks. The temperature regulating units are respectively arranged on the pressing blocks. However, the controller is electrically connected to the temperature regulating units and the actuator. The controller is adapted to control the actuator to drive the pressing blocks to respectively press against the chips on the semiconductor packaging component, so as to cause the force-generating units to apply a plurality of forces to the chips on the semiconductor packaging component. Moreover, the controller is adapted to control the temperature regulating units to respectively heat or cool the chips on the semiconductor packaging component.

Another embodiment of the present disclosure provides a semiconductor packaging component testing device. The device mainly includes a fixing base, a testing socket, a sliding frame, the foregoing pressing module capable of multi-point force application and multi-point temperature control, and a sliding generating device. The testing socket is configured to accommodate the semiconductor packaging component. The testing socket is arranged on the fixing base. The pressing module is arranged on the sliding frame. The sliding generating device is electrically connected to the controller and is arranged in at least one of the fixing base and the sliding frame. The controller is adapted to control the sliding generating device to drive the sliding frame to slide, allowing the pressing module to selectively correspond to or move away from the testing socket.

Based on the above, the pressing module capable of multi-point force application and multi-point temperature control and the semiconductor packaging component testing device having the same provided in the present disclosure may apply forces to an individual chip or specific regions of the semiconductor packaging component depending on actual requirements. The forces can be configured to be identical or vary according to requirements, and independent temperature control can be applied to each chip or region. For instance, it is applicable to different chips (e.g., SoC and HBM) or regions on semiconductor package components using advanced 2.5D or 3D packaging technologies, allowing for the provision of the necessary burn-in temperatures and predetermined downward forces for each chip or region.

### BRIEF DESCRIPTION OF THE DRAWINGS

FIG. 1 is a system block diagram of a pressing module capable of multi-point force application and multi-point temperature control according to some embodiments of the present disclosure;

FIG. 2A is a schematic diagram of a pressing module capable of multi-point force application and multi-point temperature control according to some embodiments of the present disclosure;

FIG. 2B is a schematic diagram of a pressing module capable of multi-point force application and multi-point temperature control according to some embodiments of the present disclosure;

FIG. 3A is a schematic diagram of a pressing module capable of multi-point force application and multi-point temperature control according to some embodiments of the present disclosure;

FIG. 3B is a schematic diagram of a pressing module capable of multi-point force application and multi-point temperature control according to some embodiments of the present disclosure;

FIG. 4A is a schematic diagram of a semiconductor packaging component testing device according to some embodiments of the present disclosure, showing the pressing module capable of multi-point force application and multi-point temperature control positioned in the testing position;

FIG. 4B is a schematic diagram of a semiconductor packaging component testing device according to some embodiments of the present disclosure, showing the pressing module capable of multi-point force application and multi-point temperature control positioned in the loading/unloading position;

FIG. 5 is a schematic diagram of a testing socket in a semiconductor packaging component testing device according to some embodiments of the present disclosure;

FIG. 6 is a system block diagram of a pressing module capable of multi-point force application and multi-point temperature control according to some embodiments of the present disclosure;

FIG. 7 is a top view of a semiconductor packaging component testing device according to some embodiments of the present disclosure with a pressing module capable of multi-point force application and multi-point temperature control being removed;

FIG. 8 is a perspective view of a pressing module capable of multi-point force application and multi-point temperature control according to some embodiments of the present disclosure;

FIG. 9A is a perspective view of a first pressing block in a pressing module capable of multi-point force application and multi-point temperature control according to some embodiments of the present disclosure;

FIG. 9B is a perspective view of a second pressing block in a pressing module capable of multi-point force application and multi-point temperature control according to some embodiments of the present disclosure;

FIG. 10 is a front view of a pressing module capable of multi-point force application and multi-point temperature control according to some embodiments of the present disclosure;

FIG. 11 is a top view of a first pressing block and a second pressing block in a pressing module capable of multi-point force application and multi-point temperature control according to some embodiments of the present disclosure; and

FIG. 12 is a perspective view of a first pressing block and a second pressing block in a pressing module capable of multi-point force application and multi-point temperature control according to some embodiments of the present disclosure.

### DETAILED DESCRIPTION

Various embodiments are described in detail below. However, the embodiments are merely used as examples for description and do not limit or reduce the protection scope of the present disclosure. In addition, some elements are omitted in the figures in the embodiments to clearly show the technical features of the present disclosure. Further, the same reference numeral is used for indicating the same or similar elements in all of the figures. The figures of the present disclosure are only illustrative, which are not necessarily drawn to scale, and all details are not necessarily presented in the figures.

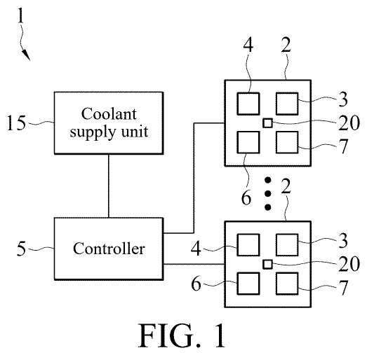

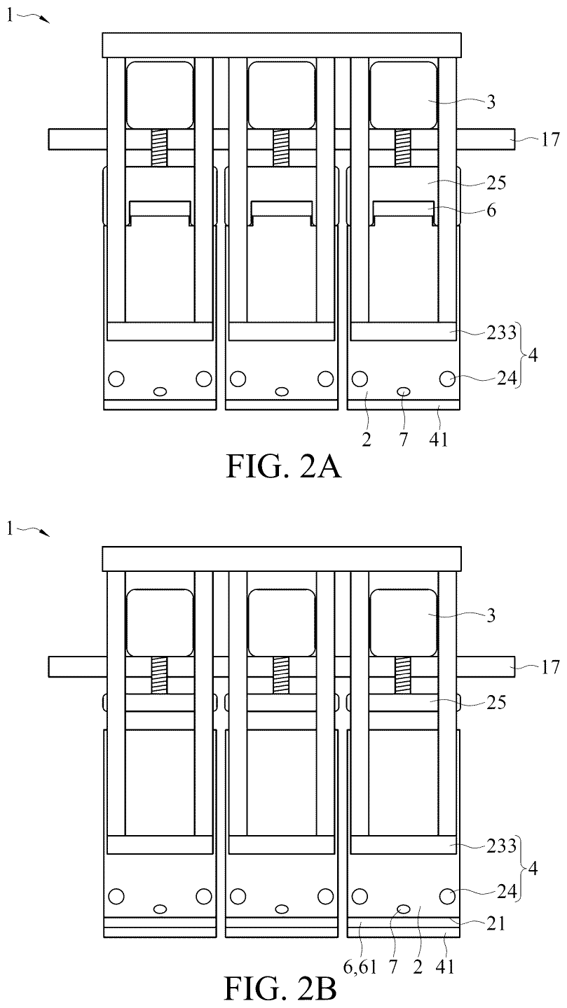

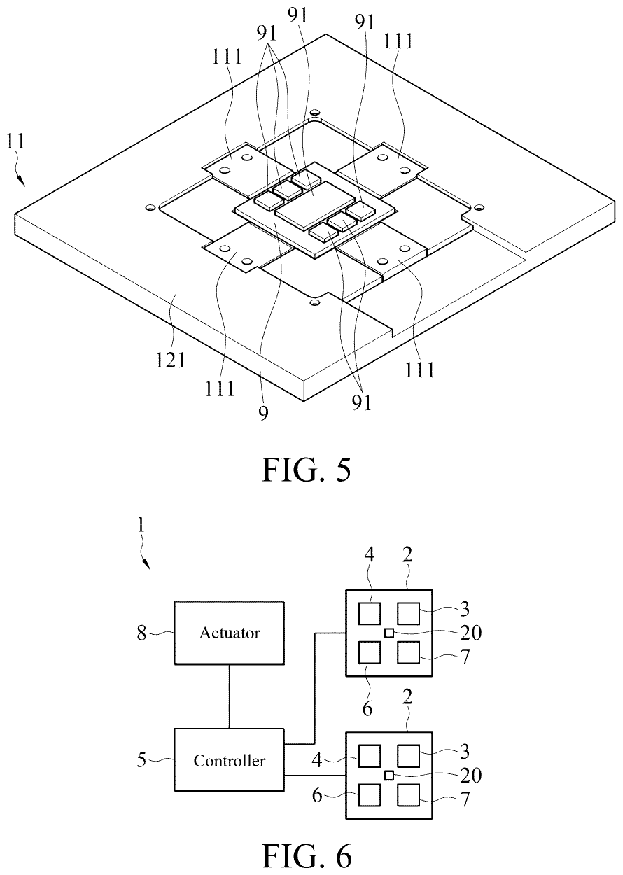

Refer to FIG. 1 and FIG. 2A together. FIG. 1 is a system block diagram of a pressing module 1 for multi-point force application and multi-point temperature control according to some embodiments of the present disclosure. FIG. 2A is a schematic diagram of a pressing module 1 for multi-point force application and multi-point temperature control according to some embodiments of the present disclosure. A pressing module capable of multi-point force application and multi-point temperature control is shown in the figures, hereinafter referred to as “pressing module 1. The module mainly includes a plurality of pressing blocks 2, a plurality of force-generating units 3, a plurality of temperature regulating units 4, and a controller 5. The pressing blocks 2 are mainly configured to correspond to a plurality of chips 91 on a semiconductor packaging component 9, as shown in FIG. 5. The semiconductor packaging component 9 shown in FIG. 5 adopts an advanced packaging technology, with multiple chips 91 arranged on its top surface, such as a central processing unit (CPU), a graphics processing unit (GPU), a high bandwidth memory (HBM), or other various types of chiplets. In another embodiment, the semiconductor packaging component 9 could also be a heterogeneous integration semiconductor packaging structure or a silicon photonics packaging component.

In addition, a plurality of pressing blocks 2 are shown in the figure, which are respectively configured to correspond to the plurality of chips 91 on the semiconductor packaging component 9. Three pressing blocks 2 are shown in the figure, which respectively correspond to three rows of chips 91 on the semiconductor packaging component 9 in FIG. 5. However, the number of pressing blocks 2 is not limited to three. In other embodiments, a quantity and positions of the pressing blocks 2 may be configured based on the specifications or characteristics of the chips 91. For example, the size, number, and placement of the pressing blocks 2 can be adjusted according to the dimensions and thermal design power (TDP) of each chip 91.

Moreover, a plurality of force-generating units 3 are shown in the figure, each connected to one of the pressing blocks 2. In some embodiments, the number of the force-generating units 3 matches the number of the pressing blocks 2; in other embodiments, these numbers may differ. For example, a plurality of force-generating units 3 may be configured for a pressing block 2 with a larger size. In addition, in some embodiments, the force-generating unit 3 may be, but is not limited to, a linear actuator, such as a linear motor, a hydraulic cylinder, or a pneumatic cylinder.

Furthermore, a plurality of temperature regulating units 4 are shown in the figure, each positioned on one of the pressing blocks 2. In some embodiments, each temperature regulating unit 4 may function as a heating unit or a cooling unit, or a combined component, device, or system that includes both heating and cooling elements. The heating unit may be a heater 24 composed of an electric heating element, a resistive heating source, or another equivalent element capable of controlled temperature increase. In another embodiment, the heating unit may also include channels or chambers through which high-temperature fluid circulates.

In addition, in the embodiment shown in the figure, the cooling unit can be configured with temperature control fluid channels 233. However, the temperature control fluid channels 233 are in communication with a coolant supply unit 15, which is responsible for providing a coolant to the temperature control fluid channel 233 of the temperature regulating units 4. In some embodiments, the coolant supply unit 15 may be a cooling distribution unit (CDU) or a chiller. In other embodiments, the cooling unit may also be a thermoelectric cooling modules (thermo-electric Module) or a vapor-compression refrigeration system (VCRS). In certain implementations, the cooling unit may also function as a condenser, incorporating serpentine channels within the pressing block 2, through which refrigerants such as liquid nitrogen, ethylene glycol, halocarbons, ammonia, sulfur dioxide, methane, or other low-temperature fluids circulate.

In addition, a controller 5 is shown in the figure, which is electrically connected to the force-generating units 3 and the temperature regulating units 4. In some embodiments, the controller 5 may be, but is not limited to, a central processing unit (CPU), a microcontroller unit (MCU), a digital signal processor (DSP), a programmable logic controller (PLC), a digital signal processor (DSP), an application specific integrated circuit (ASIC), a programmable logic device (PLD), another similar device, or a combination of the devices. In another embodiment, the controller 5 may also implement various operating functions by means of a hardware circuit. An example includes, but is not limited to, a workstation, a laptop computer, a client terminal, a server, a distributed computing system, a handheld device, or any other computing system or device. In the most basic configuration, the controller 5 may include at least one processor and a system memory.

The controller 5 is configured to control the various force-generating units 3, thereby driving each pressing block 2 to apply a downward force to each chip 91 on the semiconductor packaging component 9. In other words, the controller 5 can manage the force-generating units 3 to simultaneously apply a plurality of forces of either the same or varying magnitudes across the chips 91 on the semiconductor package component 9. Additionally, to accommodate differences in height among the chips 91, each force-generating unit 3 can produce a distinct travel stroke, ensuring that each pressing block 2 can fully contact the upper surface of each chip 91.

On the other hand, the controller 5 is also configured to manage the various temperature regulation units 4, enabling each chip 91 on the semiconductor package component 9 to be heated or cooled individually. In some embodiments, the controller 5 can adjust each temperature regulation unit 4 according to the thermal design power (TDP) of each chip 91, resulting in customized temperature control for each chip. This configuration allows either uniform temperature maintenance across all chips 91 or distinct temperature settings for each chip 91. For example, during a burn-in test, the controller 5 can manage the heater 24 to increase and maintain all chips 91 on the semiconductor package component 9 at a specific burn-in temperature.

Still refer to FIG. 2A. In some embodiments, each pressing block 2 may be equipped with a force sensing unit 6 and a temperature sensing unit 7. The force sensing units 6 and the temperature sensing units 7 are electrically connected to the controller 5. However, the force sensing units 6 are controllable to individually measure the force applied by each pressing block 2 onto each of the chips 91 on the semiconductor packaging component 9, thereby ensuring that the force-generating units 3 apply sufficient forces to the chips 91. In addition, the temperature sensing units 7 are controllable to individually measure the temperatures of the chips 91 on the semiconductor packaging component 9. These measurements work in conjunction with the temperature regulation units 4 to adjust the temperature of each chip 91, thereby ensuring that each chip 91 maintains a predetermined temperature value.

In some embodiments, the temperature values detected by the temperature sensing units 7 are to be transmitted to the controller 5. When an abnormal temperature value is detected, the controller 5 adjusts the temperature of the pressing block 2 by controlling the temperature regulation units 4 to either raise or lower the temperature of the chips 91 on the semiconductor packaging component 9. This adjustment may include modifying the temperature or flow rate of the cooling fluid or adjusting the power of the heater 24. If the abnormal temperature persists, the controller 5 will immediately send an alert message and halt the testing procedure.

In addition, in the embodiment shown in FIG. 2A, a coupling block 25 is arranged between each force-generating unit 3 and each pressing block 2. The force sensing unit 6 may be arranged between the coupling block 25 and the pressing block 2. The force sensing unit 6 may include, but is not limited to, load cells, capacitive pressure sensors, piezoresistive pressure sensors, or other types of pressure sensors.

Refer to FIG. 2B. FIG. 2B is a schematic diagram of a pressing module 1 capable of multi-point force application and multi-point temperature control according to some embodiments of the present disclosure. In the embodiment shown in FIG. 2B, a thin-film pressure sensor 61 is arranged on a contact surface 21 of each pressing block 2. The contact surface 21 is configured to contact a surface of the chip 91 on a semiconductor packaging component 9. More specifically, the thin-film pressure sensor 61 may be arranged between a lower surface of the pressing block 2 and thermal interface materials (TIM) 41.

In other embodiments, as shown in FIG. 1, each pressing block 2 may also be equipped with a monitoring unit 20, such as a tilt sensor and a proximity sensor. The monitoring unit 20, in conjunction with the force sensing unit 6, transmits feedback signals to the controller 5, which monitors the contact conditions between each pressing block 2 and the surfaces of the chips 91. Specifically, the tilt sensor can track the orientation or posture of each pressing block 2 both before and after contact with the semiconductor package structure 9, allowing for the detection of any tilt that may have occurred. The proximity sensor, in turn, ensures the full and proper contact of the pressing block 2 with the semiconductor package structure 9.

If an abnormal signal is detected by either the monitoring unit 20 or the force sensing unit 6, such as excessive downward force or improper contact between the pressing block 2 and the semiconductor package structure 9, the controller 5 can issue a control signal to halt the force generated by multiple downward force units 3. This safeguard helps prevent potential damage to the chips 91 on the semiconductor package structure 9. Additionally, if an abnormal state is detected, but the pressing block 2's level position and downward force do not exceed preset maximum thresholds, the controller 5 can issue a control signal to specific force-generating units 3 to adjust the force accordingly. This adjustment ensures each pressing block 2 maintains ideal contact with the chips 91 on the semiconductor package structure 9, allowing testing to proceed with optimal accuracy.

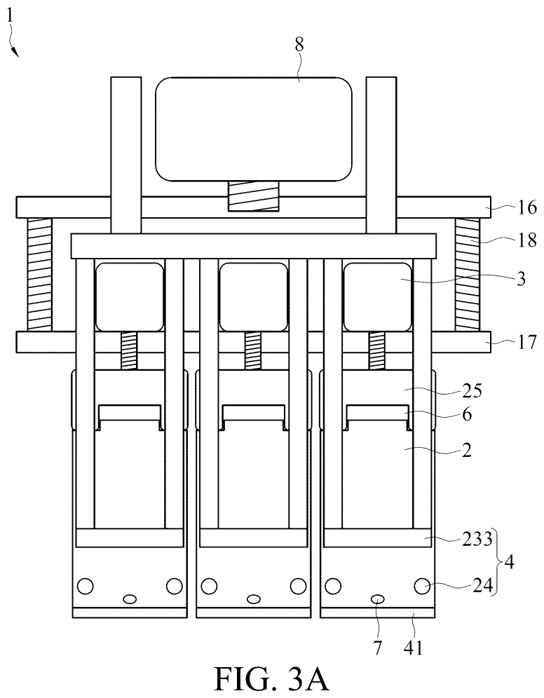

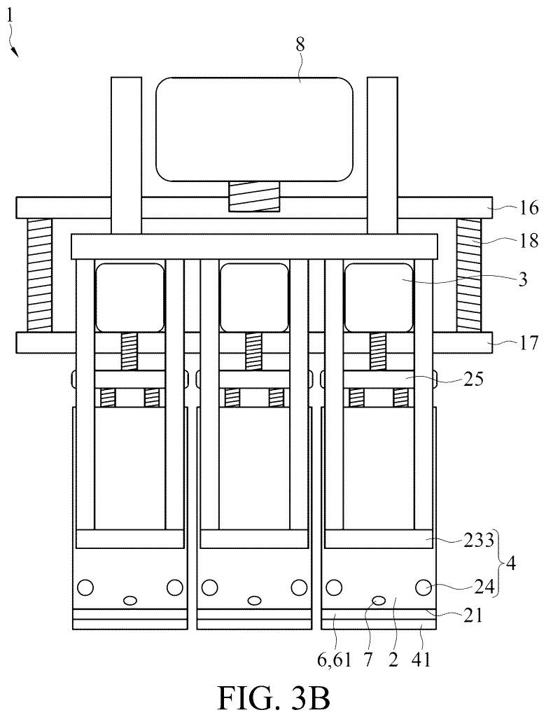

Refer to FIG. 3A. FIG. 3A is a schematic diagram of a pressing module 1 capable of multi-point force application and multi-point temperature control according to some embodiments of the present disclosure. A difference between the embodiment shown in FIG. 3A and the embodiment shown in FIG. 2A is that the pressing module 1 further includes an actuator 8, a lifting frame 16, a mounting frame 17, and a plurality of buffer members 18. The lifting frame 16 is connected to the actuator 8, and the force-generating units 3 are arranged on the mounting frame 17. The mounting frame 17 is coupled to the lifting frame 16, allowing it to slide up and down relative to the lifting frame. Additionally, the buffer elements 18 are positioned between the lifting frame 16 and the mounting frame 17, providing cushioning and controlled movement during operation.

In other words, in some embodiments, the actuator 8 provides vertical displacement to the pressing blocks 2 via the lifting frame 16 and the mounting frame 17, allowing these pressing blocks 2 to approach or press against the semiconductor package structure 9 and its chips 91. After positioning, the force-generating units 3 can then apply downward force onto the chips 91. The buffer elements 18 serve a cushioning function, which prevents damage to the semiconductor package structure 9 by avoiding potential impacts from pressing blocks 2 when the actuator 8 drives the pressing block 2 to descend. In some embodiments, the actuator 8 can function as a master actuator, providing a broader range of vertical movement, while the force-generating units 3 act as slave actuators, offering finer vertical adjustments and applying the necessary downward force.

Refer to FIG. 3B. FIG. 3B is a schematic diagram of a pressing module 1 capable of multi-point force application and multi-point temperature control according to some embodiments of the present disclosure. Similarly, the embodiment shown in FIG. 3B differs from that shown in FIG. 2B by further including an actuator 8, a lifting frame 16, a mounting frame 17, and a plurality of buffer members 18. Operating principles and effects of the components are as described in the previous paragraph. In some embodiments, the actuator 8 may be a linear actuator, such as a linear motor, hydraulic cylinder, or pneumatic cylinder. Alternatively, the actuator 8 can be composed of a compound mechanism, such as a motor paired with a ball screw or with gear and rack drive elements.

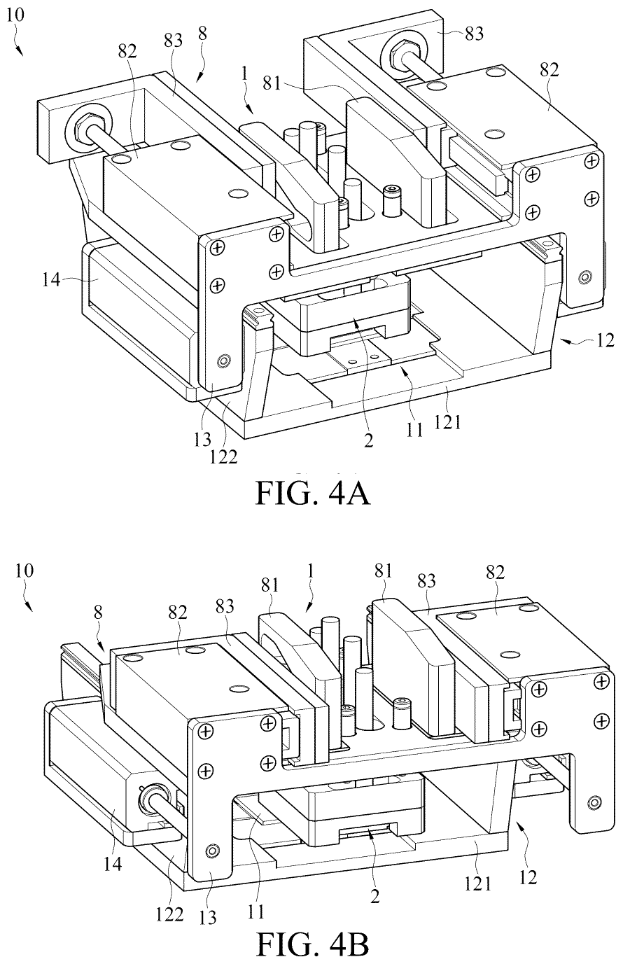

Refer to FIG. 4A, FIG. 4B, and FIG. 5 together. FIG. 4A is a schematic diagram of a semiconductor packaging component testing device 10 according to some embodiments of the present disclosure, showing the pressing module 1 capable of multi-point force application and multi-point temperature control positioned in the testing position. FIG. 4B is a schematic diagram of a semiconductor packaging component testing device 10 according to some embodiments of the present disclosure, showing the pressing module 1 capable of multi-point force application and multi-point temperature control positioned in the loading/unloading position. FIG. 5 is a schematic diagram of a testing socket 11 in a semiconductor packaging component testing device 10 according to some embodiments of the present disclosure.

The embodiments shown in FIG. 4A and FIG. 4B, a semiconductor packaging component testing device 10 is provided. This device primarily includes a fixing base 12, a testing socket 11, a sliding frame 13, and a pressing module 1. The fixing base 12 may be fixed to a workstation area of a machine. In some embodiments, the fixing base 12 may be a generally U-shaped structural member, which may include a bottom plate 121 and two side plates 122.

Refer to FIG. 5. The testing socket 11 may be arranged on the bottom plate 121. In some embodiments, the testing socket 11 may be composed of four positioning plates 111, which, together with the bottom plate 121, define a receiving space designed to accommodate the semiconductor package component 9. In addition, a plurality of probes (not shown in the figure) are further arranged in the accommodating space. These probes are primarily used for electrical contact with the contact points on the underside of the semiconductor package component 9, facilitating the transmission of power and signals.

Moreover, FIG. 4A and FIG. 4B further show a sliding frame 13, which is coupled to the fixing base 12 by using a guide rail and a guide slot. The pressing module 1 may be arranged on the sliding frame 13. This configuration allows the sliding frame 13 to move relative to the fixing base 12, enabling the pressing module 1 to move along with the sliding frame 13 above the bottom plate 121 of the fixing base 12.

Furthermore, in the embodiments shown in FIG. 4A and FIG. 4B, each of the two side plates 122 of the fixing base 12 is equipped with a sliding generating device 14, which is electrically connected to the controller 5 and connected to the sliding frame 13. In another embodiment, the sliding generating device 14 may be arranged on the sliding frame 13 and connected to the fixing base 12. In some embodiments, the sliding generating device 14 may be a linear actuator, such as a linear motor, a hydraulic cylinder, or a pneumatic cylinder.

In other words, the controller 5 may control the sliding generating device 14 to drive the sliding frame 13 to slide, enabling the pressing module 1 to either align with or move away from the testing socket 11. As shown in FIG. 4A, the pressing module 1 corresponds to the testing socket 11, that is, the pressing module 1 is located in a test position directly above the testing socket 11. In this case, the pressing module 1 may apply a force to and perform temperature control on the semiconductor packaging component 9 on the testing socket 11. On the other hand, as shown in FIG. 4B, the pressing module 1 is away from the testing socket 11 and located in a loading/unloading position. In this case, the pressing module 1 does not obstruct the area above the testing socket 11, permitting a loading/unloading device (not shown) to either retrieve the semiconductor package 9 after testing or place a new package 9 for testing.

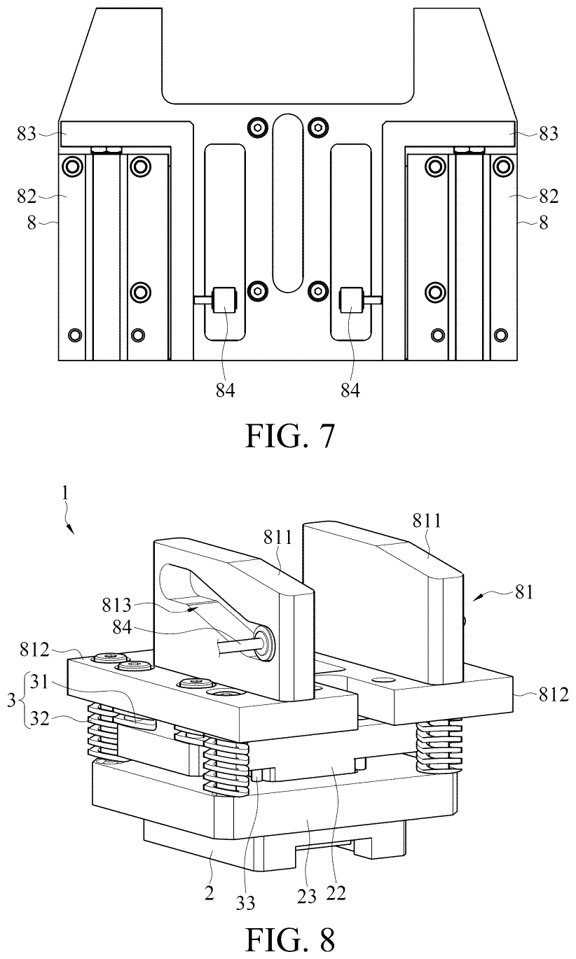

Refer to FIG. 6, FIG. 7, and FIG. 8 together. FIG. 6 is a system block diagram of a pressing module 1 capable of multi-point force application and multi-point temperature control according to some embodiments of the present disclosure. FIG. 7 is a top view of a semiconductor packaging component testing device 10 according to some embodiments of the present disclosure with a pressing module 1 capable of multi-point force application and multi-point temperature control being removed. FIG. 8 is a perspective view of a pressing module 1 capable of multi-point force application and multi-point temperature control according to some embodiments of the present disclosure. In the embodiments shown in the figures, the pressing module 1 mainly includes two pressing blocks 2, a plurality of force-generating units 3, two temperature regulating units 4, a controller 5, two force sensing units 6, two temperature sensing units 7, two monitoring units 20, and an actuator 8.

As shown in the figure, the pressing blocks 2 respectively correspond to a plurality of chips 91 on the semiconductor packaging component 9. The force-generating units 3 are coupled to the pressing blocks 2. Each pressing block 2 is equipped with a temperature regulating units 4, a temperature sensing units 7, a monitoring units 20, and a force sensing units 6. Additionally, the controller 5 is electrically connected to the temperature regulating units 4, the force sensing unit 6, the temperature sensing units 7, the monitoring units 20, and the actuator 8.

In some embodiments, the controller 5 is configured to control the actuator 8 to drive the pressing blocks 2 to respectively press against the chips 91 on the semiconductor packaging component 9, so as to drive the force-generating units 3 to respectively apply a plurality of forces to the chips 91 on the semiconductor packaging component 9. For the configuration and functions of the temperature regulating units 4, the force sensing units 6, the monitoring units 20, and the temperature sensing units 7, reference may be made to the foregoing embodiments.

In the embodiment shown in FIG. 8, the pressing module 1 further includes a force application plate 81. The pressing blocks 2 include a first pressing block 22 and a second pressing block 23. A lower surface of the first pressing block 22 corresponds to the chip 91 located in the center of the semiconductor packaging component 9 (refer to FIG. 5). A lower surface of the second pressing block 23 corresponds to the chips 91 located in two side rows on the semiconductor packaging component 9 (refer to FIG. 5).

The force-generating units 3 include a plurality of first elastic members 31 and a plurality of second elastic members 32. The first elastic members 31 are arranged between the force application plate 81 and the first pressing block 22. The second elastic members 32 are arranged between the force application plate 81 and the second pressing block 23. The first elastic members 31 and the second elastic members 32 may be compression springs with varying allowable compression amounts. In addition, in some embodiments, the first elastic members 31 may be arranged at four corners of the first pressing block 22. Similarly, the second elastic members 32 may be arranged at four corners of the second pressing block 23.

In this embodiment, when the actuator 8 is controlled to drive the force application plate 81 to move toward the first pressing block 22 and the second pressing block 23, it causes the first elastic members 31 and the second elastic members 32 to exert varying or uniform forces on the chips 91 of the semiconductor packaging component 9 respectively through the first pressing block 22 and the second pressing block 23.

In addition, refer to FIG. 5 again. The testing socket 11 shown in the figure is composed of four positioning plates 111. However, in some embodiments, the positioning plates 111 are designed to match with the first pressing block 22 and the second pressing block 23, particularly in terms of height. In other words, when the pressing module 1 performs pressing, the positioning plates 111 may respectively limit pressing travels of the first pressing block 22 and the second pressing block 23, preventing the chips 91 from being damaged due to excessive downward force.

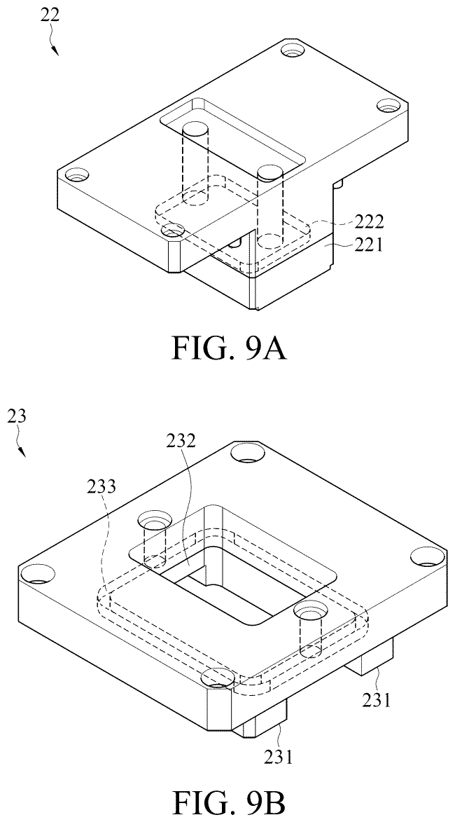

Refer to FIG. 9A and FIG. 9B together. FIG. 9A is a perspective view of a first pressing block 22 in a pressing module 1 capable of multi-point force application and multi-point temperature control according to some embodiments of the present disclosure. FIG. 9B is a perspective view of a second pressing block 23 in a pressing module 1 capable of multi-point force application and multi-point temperature control according to some embodiments of the present disclosure. In some embodiments, the first pressing block 22 includes a central protrusion 221, which is configured to contact the chip 91 located in the center of the semiconductor packaging component 9 (refer to FIG. 5). The second pressing block 23 includes two protruded frame portions 231 and a central slot 232. The two protruded frame portions 231 are respectively arranged on two opposite sides of the central slot 232. The two protruded frame portions 231 are configured to contact the chips 91 located in two side rows of the semiconductor packaging component 9 (also refer to FIG. 5).

In addition, the central protrusion 221 of the first pressing block 22 is located in the central slot 232 of the second pressing block 23. The first pressing block and the second pressing block are loosely fitted, that is, the first pressing block 22 and the second pressing block 23 may move independently without interfering with each other. In some embodiments, a plurality of buffer springs 33 may be further arranged between the first pressing block 22 and the second pressing block 23 (refer to FIG. 8), which are configured to prevent the first pressing block and the second pressing block from colliding with each other, and to assist in their return to the original position while maintaining a specific distance between them.

In the embodiments shown in FIG. 9A and FIG. 9B, the temperature regulating unit 4 includes a temperature control fluid chamber 222 and a temperature control fluid channel 233. The temperature control fluid chamber 222 is arranged within the central protrusion 221 of the first pressing block 22, while the temperature control fluid channel 233 is arranged within the second pressing block 23. Accordingly, the temperature control fluid chamber 222 and the temperature control fluid channel 233 are respectively supplied with a high-temperature control fluid or low-temperature control fluid, so that the first pressing block 22 and the second pressing block 23 can independently heat or cool the chips 91 on the semiconductor packaging component 9. In some embodiments, a cooling distribution unit (CDU) or a chiller may be used to provide the low-temperature fluid to the temperature control fluid chamber 222 and the temperature control fluid channel 233.

Refer to FIG. 7 and FIG. 8 together. In the embodiments shown in the figures, the force application plate 81 includes two vertical portions 811 and a bottom plate portion 812. The vertical portions 811 are vertically connected to the bottom plate portion 812, and each of the vertical portions 811 includes a diagonal slot 813. One end of the diagonal slot 813 is proximate to the bottom plate portion 812, and the other end is distal to the bottom plate portion 812. In addition, the actuator 8 includes a linear displacement generating unit 82, a horizontal slider 83, and a guide rod 84. The horizontal slider 83 is coupled to the linear displacement generating unit 82. One end of the guide rod 84 is connected to the horizontal slider 83, and the other end is located within the diagonal slot 813 of the vertical portion 811.

Accordingly, when the linear displacement generating unit 82 drives the horizontal slider 83 to move horizontally, it causes the guide rod 84 to slide within the diagonal slot 813. This, in turn, drives the force application plate 81 to approach or away from the first pressing block 22 and the second pressing block 23. In other words, through the foregoing mechanism design, the horizontal motion of the linear displacement generating unit 82 is converted into vertical movement of the force application plate 81. This transformation enables a more compact assembly of the entire mechanism, significantly reducing its overall height.

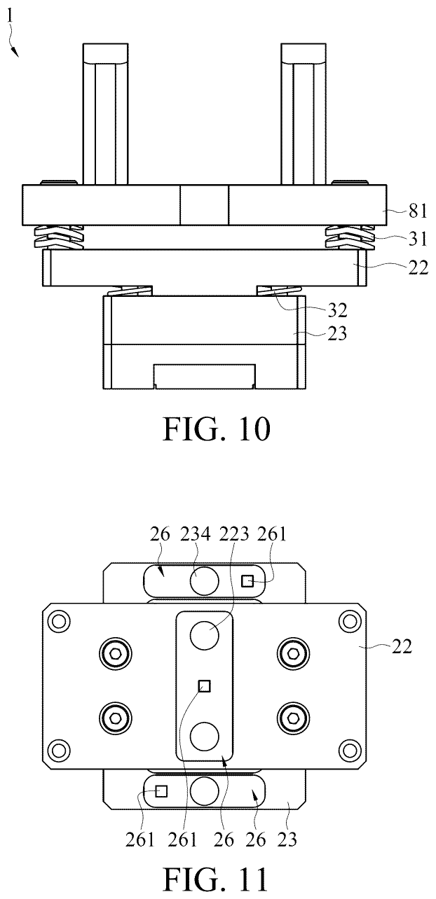

Refer to FIG. 10 together. FIG. 10 is a front view of a pressing module 1 capable of multi-point force application and multi-point temperature control according to some embodiments of the present disclosure. A main difference between the embodiment shown in FIG. 10 and the embodiment shown in FIG. 8 is that in the embodiment shown in FIG. 10, the first elastic members 31 are arranged between the force application plate 81 and the first pressing block 22, while the second elastic members 32 are arranged between the first pressing block 22 and the second pressing block 23.

When the controller 5 controls the actuator 8 to drive the force application plate 81 to move toward the first pressing block 22 and the second pressing block 23, this action causes the first elastic members 31 to apply a downward force on the chips 91 on the semiconductor packaging component 9 through the first pressing block 22. Simultaneously, this also enables the first elastic members 31 and the second elastic members 32 to apply an another downward force on other chips 91 on the semiconductor packaging component 9 through the second pressing block 23.

It should be further noted that the first pressing block 22 is only affected by compression elastic forces from the first elastic members 31, while the second pressing block 23 is affected by the combined compressive forces of both the first elastic members 31 and the second elastic members 32. Therefore, the first pressing block 22 and the second pressing block 23 respectively generate two forces of different magnitudes.

Refer to FIG. 11. FIG. 11 is a top view of a first pressing block 22 and a second pressing block 23 in a pressing module 1 capable of multi-point force application and multi-point temperature control according to some embodiments of the present disclosure. As shown in FIG. 11, the first pressing block 22 includes two fluid ports 223, which are both in communication with the temperature control fluid chamber 222 inside the first pressing block 22 (refer to FIG. 9A). In addition, the second pressing block 23 includes two fluid channel ports 234, which are both in communication with the temperature control fluid channel 233 inside the second pressing block 23 (refer to FIG. 9B).

In fact, each of the two fluid ports 223 and the two fluid channel ports 234 includes an inlet and an outlet. The inlets are configured for a temperature control fluid to flow into the temperature control fluid chamber 222 (refer to FIG. 9A) and the temperature control fluid channel 233 (refer to FIG. 9B), and the outlets are configured for the temperature control fluid to flow out. In addition, as shown in the figure, the two fluid ports 223 and the two fluid channel ports 234 are respectively arranged in a leak-proof recess 26. This recess 26 is designed to collect any leaked fluid from the fluid ports 223 and channel ports 234, thereby preventing it from spilling onto the semiconductor package 9 or other electronic components, which could lead to a short circuit. In other embodiments, a leak detector 261 may be installed within the leak-proof recess 26 to promptly detect any leaks and issue immediate alerts for timely handling.

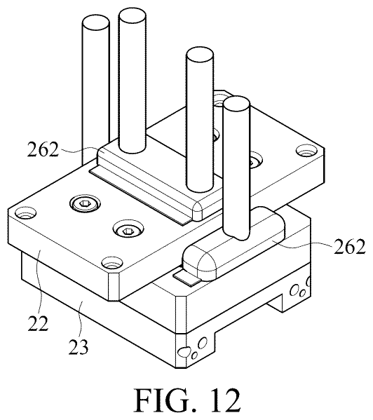

Refer to FIG. 12. FIG. 12 is a perspective view of a first pressing block 22 and a second pressing block 23 in a pressing module 1 capable of multi-point force application and multi-point temperature control according to some embodiments of the present disclosure. In the embodiment shown in FIG. 12, each leak-proof recess 26 may be equipped with a cover 262 to prevent any leaked fluid from splashing or spilling out.

Although the present disclosure has been described in considerable detail with reference to certain preferred embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. A pressing module capable of multi-point force application and multi-point temperature control, the module comprising:
a plurality of pressing blocks, respectively corresponding to a plurality of chips on a semiconductor packaging component;
a plurality of force-generating units, respectively coupled to the plurality of pressing blocks;
a plurality of temperature regulating units, respectively arranged on the plurality of pressing blocks; and
a controller, electrically connected to the plurality of force-generating units and the plurality of temperature regulating units, wherein
the controller is adapted to control the plurality of force-generating units to drive the plurality of pressing blocks to respectively apply forces to the plurality of chips on the semiconductor packaging component, and the controller is adapted to control the plurality of temperature regulating units to respectively heat or cool the plurality of chips on the semiconductor packaging component.

2. The pressing module capable of multi-point force application and multi-point temperature control according to claim 1, further comprising a plurality of force sensing units respectively arranged on the plurality of pressing blocks and electrically connected to the controller, wherein the controller is adapted to control the plurality of force sensing units to respectively measure the forces applied by the plurality of pressing blocks to the plurality of chips on the semiconductor packaging component.

3. The pressing module capable of multi-point force application and multi-point temperature control according to claim 2, wherein the plurality of force sensing units comprise a plurality of thin-film pressure sensors, each of the plurality of thin-film pressure sensors are respectively arranged on a contact surface of one of the plurality of pressing blocks, and the contact surface is configured to contact the plurality of chips on the semiconductor packaging component.

4. The pressing module capable of multi-point force application and multi-point temperature control according to claim 2, comprising a plurality of coupling blocks, wherein the plurality of coupling blocks are respectively between the plurality of force-generating units and the plurality of pressing blocks, and the plurality of force sensing units are respectively located between the plurality of coupling blocks and the plurality of pressing blocks.

5. The pressing module capable of multi-point force application and multi-point temperature control according to claim 1, further comprising a plurality of temperature sensing units respectively arranged on the plurality of pressing blocks and electrically connected to the controller, wherein the controller is adapted to control the plurality of temperature sensing units to respectively measure temperatures of the plurality of chips on the semiconductor packaging component.

6. The pressing module capable of multi-point force application and multi-point temperature control according to claim 1, further comprising an actuator electrically connected to the controller, wherein the controller is adapted to control the actuator to drive the plurality of pressing blocks to respectively press against the plurality of chips on the semiconductor packaging component.

7. The pressing module capable of multi-point force application and multi-point temperature control according to claim 6, further comprising a lifting frame, a mounting frame, and a plurality of buffer members, wherein the lifting frame is connected to the actuator, the plurality of force-generating units are arranged on the mounting frame, and the mounting frame is coupled to the lifting frame through the plurality of buffer members.

8. The pressing module capable of multi-point force application and multi-point temperature control according to claim 1, further comprising a coolant supply unit, wherein the coolant supply unit is electrically connected to the controller, each temperature regulating units comprises a temperature control fluid channel and a heater, the temperature control fluid channel is in communication with the coolant supply unit, the controller is adapted to control the coolant supply unit to provide a coolant to the temperature control fluid channel of the plurality of temperature regulating units, and the controller is adapted to control the heater to heat the plurality of chips on the semiconductor packaging component.

9. The pressing module capable of multi-point force application and multi-point temperature control according to claim 1, further comprising a plurality of monitoring units respectively arranged on the plurality of pressing blocks and electrically connected to the controller, wherein the controller is adapted to control the plurality of monitoring units to respectively sense postures of the plurality of pressing blocks or a contact condition between each of the plurality of pressing blocks and the semiconductor packaging component.

10. A pressing module capable of multi-point force application and multi-point temperature control, the module comprising:
a plurality of pressing blocks, respectively corresponding to a plurality of chips on a semiconductor packaging component;
a plurality of force-generating units, coupled to the plurality of pressing blocks;
a plurality of temperature regulating units, respectively arranged on the plurality of pressing blocks;
an actuator; and
a controller, electrically connected to the plurality of temperature regulating units and the actuator, wherein
the controller is adapted to control the actuator to drive the plurality of pressing blocks to respectively press against the plurality of chips on the semiconductor packaging component, so as to cause the plurality of force-generating units to apply a plurality of forces to the plurality of chips on the semiconductor packaging component; the controller is adapted to control the plurality of temperature regulating units to respectively heat or cool the plurality of chips on the semiconductor packaging component.

11. The pressing module capable of multi-point force application and multi-point temperature control according to claim 10, further comprising a force application plate, wherein the plurality of pressing blocks comprise a first pressing block and a second pressing block, the plurality of force-generating units comprise a plurality of first elastic members and a plurality of second elastic members, the first elastic members are arranged between the force application plate and the first pressing block, the second elastic members are arranged between the force application plate and the second pressing block; wherein the controller is adapted to control the actuator to drive the force application plate to move toward the first pressing block and the second pressing block, thereby causing the plurality of first elastic members and the plurality of second elastic members to apply the plurality of forces respectively through the first pressing block and the second pressing block.

12. The pressing module capable of multi-point force application and multi-point temperature control according to claim 11, wherein the first pressing block comprises a central protrusion, the second pressing block comprises at least a protruded frame portion and a central slot, the central protrusion of the first pressing block is located in the central slot of the second pressing block; the plurality of temperature regulating units comprise a temperature control fluid chamber and a temperature control fluid channel; the temperature control fluid chamber is arranged within the central protrusion, and the temperature control fluid channel is arranged in the second pressing block.

13. The pressing module capable of multi-point force application and multi-point temperature control according to claim 11, wherein the force application plate comprises at least one vertical portion and a bottom plate portion, the at least one vertical portion is vertically connected to the bottom plate portion, the at least one vertical portion comprises a diagonal slot, one end of the diagonal slot being proximate to the bottom plate portion, and the other end being distal to the bottom plate portion ; the actuator comprises a linear displacement generating unit, a horizontal slider, and a guide rod, the horizontal slider is coupled to the linear displacement generating unit; one end of the guide rod is connected to the horizontal slider, the other end is located within the diagonal slot of the at least one vertical portion; the linear displacement generating unit is adapted to drive the horizontal slider to generate a horizontal movement, thereby causing the guide rod to slide within the diagonal slot to drive the force application plate to move toward or away from the first pressing block and the second pressing block.

14. The pressing module capable of multi-point force application and multi-point temperature control according to claim 10, further comprising a force application plate, wherein the plurality of pressing blocks comprise a first pressing block and a second pressing block, the plurality of force-generating units comprise a plurality of first elastic members and a plurality of second elastic members, the first elastic members are arranged between the force application plate and the first pressing block, the second elastic members are arranged between the first pressing block and the second pressing block ; wherein the controller is adapted to control the actuator to drive the force application plate to move toward the first pressing block and the second pressing block, thereby causing the plurality of first elastic members to apply at least one of the plurality of forces through the first pressing block, and thereby causing the plurality of first elastic members and the plurality of second elastic members to apply at least one of the plurality of forces through the second pressing block.

15. A semiconductor packaging component testing device, comprising:
a fixing base;
a testing socket, configured to accommodate a semiconductor packaging component, wherein the testing socket is arranged on the fixing base;
a sliding frame, coupled to the fixing base;
the pressing module capable of multi-point force application and multi-point temperature control according to claim 1, arranged on the sliding frame; and
a sliding generating device, electrically connected to the controller and arranged in the fixing base or the sliding frame, wherein
the controller is adapted to control the sliding generating device to drive the sliding frame to slide, allowing the pressing module capable of multi-point force application and multi-point temperature control to selectively correspond to or move away from the testing socket.

16. The semiconductor packaging component testing device according to claim 15, wherein the testing socket comprises a plurality of positioning plates, the fixing base comprises a bottom plate, the plurality of positioning plates are arranged on the bottom plate, and the plurality of positioning plates and the bottom plate define an accommodating space for receiving the semiconductor packaging component.
